(19) United States
(12) Patent Application Publication
(10) Pub. No.: US 2022/0076984 A1
(43) Pub. Date: Mar. 10, 2022

(54) Multi-Axis Motion System with Decoupled Wafer Chuck Support and Methods of Use and Manufacture

(71) Applicant: Newport Corporation, Irvine, CA (US)

(72) Inventors: Eric Durand, Amilly (FR); Franck Duquenoy, Olivet (FR); Joël Mendes Pereira, Saint-Jean-de-Braye (FR)

(73) Assignee: Newport Corporation, Irvine, CA (US)

(21) Appl. No.: 17/017,402

(22) Filed: Sep. 10, 2020

(51) Int. Cl. H01L 21/683; H01L 21/687

(52) U.S. Cl. CPC H01L 21/6838; G06T 7/0004; H01L 21/687

(57) ABSTRACT

The present application discloses a multi-axis motion system and methods of use, using an air bearing configured to position a semiconductor wafer chuck support relative to an inspection device. The air bearing includes a vacuum clamping function operative to secure the wafer chuck support to a surface formed on the underside of a structure that houses the inspection device. In one embodiment, the system includes a first positioner operative to position a carriage assembly in a first direction, the carriage assembly including a second positioner and a third positioner operative to selectively and independently travel in a second direction orthogonal to the first direction. The chuck support is secured to the positioners by one or more pivoting decoupling systems configured to transmit actuation forces from the positioners in the first and second directions, allowing the chuck support to be decoupled from the positioners when the chuck support is vacuum clamped to the underside of the structure.

### BACKGROUND

Multi-axis positioning systems are used for a variety of semiconductor manufacturing applications. One such application is wafer inspection, where a semiconductor wafer mounted on a wafer support is positioned within the field of view of an inspection camera. During this inspection, the wafer support may be positioned in multiple axes or directions to locate a variety of semiconductor device features within the field of view of the inspection camera. The miniaturization of semiconductor devices has increased the requirements for the precision and stability of multi-axis positioning systems for these applications. Numerous positioners such as motion stages arranged in stacks are used to move the wafer support. These stacks of positioners can introduce errors and stability problems when moving the wafer support at high speeds.

While prior art multi-axis positioning systems have proven useful in the past a number of shortcomings have been identified. For example, multi-axis positioning systems that use stacks of motion stages to control movement of the semiconductor wafer are limited in their ability to hold the wafer steady enough for the inspection camera to resolve very small semiconductor structures.

In light of the foregoing, there is an ongoing need for an improved motion system to provide very high stability by decoupling the wafer support from the positioner.

### SUMMARY

The present application is directed to a multi-axis motion system with a decoupled wafer chuck support useful for the inspection and processing of semiconductor wafers.

In one embodiment, the multi-axis motion system comprises at least one structure assembly including at least one lower structure, at least one intermediate structure secured to the lower structure and at least one upper structure secured to the intermediate structure, the upper structure having at least one upper structure body with at least one lower surface with at least one passive reference surface formed thereon, the upper structure further including at least one aperture formed in the upper structure body. The lower structure is configured to support a first positioner operative to support and change the position of at least one carriage assembly in a first direction, the carriage assembly including at least one second positioner secured to one end of the carriage assembly, the second positioner including at least one frame configured to travel thereon in a second direction substantially orthogonal to the first direction. At least one third positioner may be secured to the opposing end of the carriage assembly, the third positioner including at least one frame configured to selectively travel thereon in the second direction independently of the frame of the second positioner. At least one decoupling linkage assembly configured to support at least one pivoting decoupling system may be secured to at least one of the second positioner and the third positioner, wherein the decoupling linkage assembly is configured to allow the pivoting decoupling system to freely slide in the first direction. The pivoting decoupling system is rotatably coupled to at least one of the decoupling linkage assembly, the second positioner, and the third positioner, the pivoting decoupling systems configured to support at least one chuck support assembly having at least one connection region secured to the pivoting decoupling system. In one embodiment, the first positioner includes at least one linear motor actuator, at least one guide rail secured to the structure assembly, and one or more sliding blocks configured to travel along the guide rail. In one embodiment, at least one of the first positioner, the second positioner, and the third positioner include a linear motor actuators. In another embodiment, the positioners include actuators selected from the group consisting of servo-motor driven linear motion stages, stepper motor-driven linear stages and piezomotor-driven motion stages.

In one embodiment, the pivoting decoupling system includes at least one pivot assembly configured to be rotatably secured to the decoupling linkage assembly, at least one interface assembly configured to be secured to the chuck support assembly, and at least one decoupling interface device having at least one blade member with at least one outer region configured to be secured to the pivot assembly, and at least one flexure region configured to be secured to the interface assembly, wherein the decoupling interface device is operative to transmit actuating forces from the pivot assembly to the interface assembly in at least one of the first direction and the second direction, and to provide a biasing force between the pivot assembly and the interface assembly in a third direction. The decoupling interface device may include a plurality of blade members with a damping material disposed between the blade members.

In another embodiment, the pivoting decoupling system includes at least one decoupling interface device including at least one blade member having at least one blade member body with at least one aperture, one or more outer regions, a plurality of outer coupling passages, a plurality of inner coupling passages, and one or more flexure regions formed therein. The pivoting decoupling system further includes at least one pivot assembly having least one first bearing plate with at least one first bearing plate body with at least one bearing recess and one or more coupling passages formed therein, the bearing recess configured to accept a portion of a pivot bearing therein, the pivot bearing configured to accept at least one pivot body therein. The pivot assembly further includes at least one second bearing plate including at least one second bearing plate body with a least one bearing recess formed therein, the bearing recess configured to accept a portion of the pivot bearing therein, the second bearing plate body further including one or more inner coupling passages and one or more outer coupling passages formed therein. One or more couplers configured to traverse through the inner coupling passages in the second bearing plate body may engage the coupling passages in the first bearing plate, thereby retaining the pivot bearing between the first bearing plate and the second bearing plate. One or more intermediate plate members are provided, each with a plurality of coupling passages formed therein. A plurality of couplers traverse through the outer coupling passages of the second bearing plate, through a plurality of outer coupling passages of the blade member body, engaging the coupling passages in the outer intermediate plate members, thereby securely retaining the outer region of the blade member body between the second bearing plate and the outer intermediate plate members.

In this embodiment, the pivoting decoupling system further includes at least one interface assembly having at least one interface plate with a plurality of outer coupling passages and a plurality of inner coupling passages formed therein, and one or more inner intermediate plate members with a plurality of coupling passages formed therein. A plurality of couplers configured to traverse through the inner coupling passages of the interface plate and the inner coupling passages of the blade member body, engage the coupling passages formed in the inner intermediate plate members, thereby securing the flexure regions of the blade member body between the interface plate and the inner intermediate plate members. The interface assembly is configured to support a chuck support assembly, the chuck support assembly including a chuck support body with an aperture and a plurality of raised regions formed therein, and at least one connection region configured to be secured to the pivoting decoupling systems via the interface assembly. The chuck support assembly further includes one or more fluid pressure inlets in communication with a fluid pressure source via a fluid pressure conduit, and one or more vacuum inlets in communication with a vacuum source via at least one vacuum conduit. The chuck support assembly further includes a plurality of fluid pressure passages and a plurality of vacuum passages formed in the chuck support body, one or more active reference surfaces formed on the raised regions, the active reference surfaces including one or more fluid pressure ports in communication with the fluid pressure inlets via the fluid pressure passages. The chuck support body further includes one or more vacuum recesses with one or more vacuum ports formed in the raised regions, the vacuum ports in pneumatic communication with the vacuum inlets via the vacuum passages, wherein the active reference surfaces and the vacuum recesses are configured to form an air bearing operative to allow the chuck support assembly to be positioned relative to the aperture formed in the upper structure. The second and third positioners may further include at least one upper guide rail secured to at least one of the first guide rail base and the second guide rail base, including one or more upper sliding blocks configured to support at least one frame configured to slide along the upper guide rail, the frame including at least one linear motor coil assembly secured thereto. At least one linear motor magnet assembly configured to allow the linear motor coil assembly to travel therein is mounted to at least one of the first guide rail base and the second guide rail base. The linear motor magnet assembly is operative to exert an electromotive force on the linear motor coil assembly, thereby forcing the frame to undergo a change in linear position along the upper guide rail. The second positioner and the third positioner may further include at least one lower guide rail secured to at least one of the first guide rail base and the second guide rail base, with one or more lower sliding blocks secured to the frame and configured to slide along the lower guide rail. One or more encoders configured to sense the position of the frame may be secured to the first guide rail base and the second guide rail base. One or more limit switch assemblies configured to sense the presence of the frame may secured to the first guide rail base and the second guide rail base.

In another embodiment, the multi-axis motion system comprises a system controller including a fluid pressure control system with at least one fluid pressure source, a vacuum control system with at least one vacuum source, and at least one motion control system. At least one structure assembly is provided, the structure assembly being configured to support a first positioner configured to slidably support at least one carriage assembly thereon and to drive the carriage assembly in a first direction. The carriage assembly may include at least one second positioner secured to one end of the carriage assembly, the second positioner configured to travel in a second direction substantially orthogonal to the first direction. The carriage assembly may further include at least one third positioner configured to selectively travel in the second direction independently of the second positioner. A decoupling linkage assembly configured to support at least one pivoting decoupling system may be mounted to at least one of the second positioner and the third positioner, the decoupling linkage assembly being configured to allow the pivoting decoupling system to freely slide in the first direction. At least one chuck support assembly including at least one connection region may be secured to the pivoting decoupling systems.

The present application also discloses a method of positioning a chuck support assembly. In one embodiment, the method includes providing at least one system controller operative to selectively command at least one pressure control system, at least one vacuum control system, and at least one motion control system, these systems being collectively configured to execute at least one unclamping mode, at least one air bearing mode and at least one clamping mode. In the unclamping mode, the system controller may command the vacuum control system to reduce the vacuum supplied to one or more vacuum regions formed in the chuck support assembly proximal to at least one passive reference surface formed on a lower surface of an upper structure. In the air bearing mode, the system controller may command the pressure control system to supply fluid pressure to at least one active reference surface formed on the chuck support assembly, and synchronously command the motion control system to engage at least one of a first positioner, a second positioner and a third positioner, to move the chuck support assembly in at least one of a first direction and a second direction relative to at least one aperture formed in the upper structure. The chuck support assembly is moved from a first position to a second position, or undergoes a change in angular orientation relative to the aperture. In the clamping mode, the system controller may command the pressure control system to decrease the fluid pressure supplied to the active reference surface, while synchronously commanding the vacuum control system to increase the vacuum supplied to the vacuum regions. In this mode, the system controller also synchronously commands the motion control system to disengage at least one of the first positioner, the second positioner, and the third positioner, thereby decoupling the chuck support assembly from the positioners and clamping the chuck support assembly to the passive reference surface.

Other features and advantages of the multi-axis motion system with a decoupled wafer chuck support as described herein will become more apparent from a consideration of the following detailed description.

### BRIEF DESCRIPTION OF THE DRAWINGS

Various embodiments of an multi-axis motion system with a decoupled wafer chuck support and methods of use and manufacture will be explained in more detail by way of the accompanying drawings, wherein:

FIG. 1 shows a schematic of an exemplary multi-axis motion control system according to one embodiment;

FIGS. 2 and 3 show views of a system schematic of an embodiment of the motion system components of a multi-axis motion control system;

FIG. 4 shows a side view of the embodiment of the multi-axis positioning system shown in FIGS. 2 and 3;

FIG. 5 shows an exploded perspective view of the embodiment of the multi-axis motion control system shown in FIG. 4;

FIG. 6 shows an elevated perspective view of the carriage and lower structure forming the embodiment of the multi-axis motion control system shown in FIG. 4;

FIG. 7 shows an elevated perspective view an embodiment of the carriage assembly shown in in FIGS. 5 and 6;

FIG. 8 shows an elevated perspective view of an embodiment of the chuck support shown in FIGS. 4 and 5;

FIG. 9 shows an exploded perspective view of an embodiment of a pivoting decoupling system of the multi-axis motion control system shown in FIG. 4;

FIG. 10 shows an exploded section view of the embodiment of a pivot assembly shown in FIG. 9;

FIG. 11 shows an exploded perspective view of the embodiment of a pivot assembly shown in FIG. 10;

FIG. 12 shows an exploded section view of an embodiment of an interface assembly shown in FIG. 9; and

FIG. 13 shows an exploded view of the embodiment of the interface assembly shown in FIG. 12.

### DETAILED DESCRIPTION

Example embodiments are described herein with reference to the accompanying drawings. Unless otherwise expressly stated, in the drawings the sizes, positions, etc., of components, features, elements, etc., as well as any distances therebetween, are not necessarily to scale, but are exaggerated for clarity. In the drawings, like numbers refer to like elements throughout. Thus, the same or similar numbers may be described with reference to other drawings even if they are neither mentioned nor described in the corresponding drawing. Also, even elements that are not denoted by reference numbers may be described with reference to other drawings.

The terminology used herein is for the purpose of describing particular examplary embodiments only and is not intended to be limiting. Unless otherwise defined, all terms (including technical and scientific terms) used herein have the same meaning as commonly understood by one of ordinary skill in the art. As used herein, the singular forms “a,” “an” and “the” are intended to include the plural forms as well, unless the context clearly indicates otherwise. It should be recognized that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless indicated otherwise, terms such as “first,” “second,” etc., are only used to distinguish one element from another. For example, one coupler could be termed a “first coupler” and similarly, another node could be termed a “second coupler”, or vice versa.

Unless indicated otherwise, spatially relative terms, such as “below,” “beneath,” “lower,” “above,” and “upper,” “opposing,” and the like, may be used herein for ease of description to describe one element or feature's relationship to another element or feature, as illustrated in the FIGS. It should be recognized that the spatially relative terms are intended to encompass different orientations in addition to the orientation depicted in the FIGS. For example, if an object in the FIGS. is turned over, elements described as “below” or “beneath” other elements or features would then be oriented “above” the other elements or features. Thus, the exemplary term “below” can encompass both an orientation of above and below. An object may be otherwise oriented (e.g., rotated 90 degrees or at other orientations) and the spatially relative descriptors used herein may be interpreted accordingly.

The paragraph numbers used herein are for organizational purposes only and, unless explicitly stated otherwise, are not to be construed as limiting the subject matter described. It will be appreciated that many different forms, embodiments and combinations are possible without deviating from the spirit and teachings of this disclosure and so this disclosure should not be construed as limited to the example embodiments set forth herein. Rather, these examples and embodiments are provided so that this disclosure will be thorough and complete, and will convey the scope of the disclosure to those skilled in the art.

An XYZ & θZ reference coordinate system graphic is shown in the bottom left corner of each of the FIGS., laying out the basic orientation of various axes, directions, and degrees of freedom used in the present disclosure. This graphic is intended only to orient the reader of the patent for ease of understanding and to provide clarity and contrast between the location and relative movement of the various elements, components and systems described herein. This graphic is not intended to mean that any of the axes, directions of motion, degrees of freedom, or angular orientations of any of the disclosed components overlap each other or are orthogonal to each other.

The term “air bearing” is a term known in the art, and throughout this disclosure may be used generically, and it will be appreciated that any variety of gasses or other fluids may be used therewith. As such, the terms “fluid pressure”, “positive pressure”, or “positive fluid pressure” can be construed to denote positive pressure of air, carbon dioxide, nitrogen, inert gasses, and the like, or liquids such as water, oils and the like.

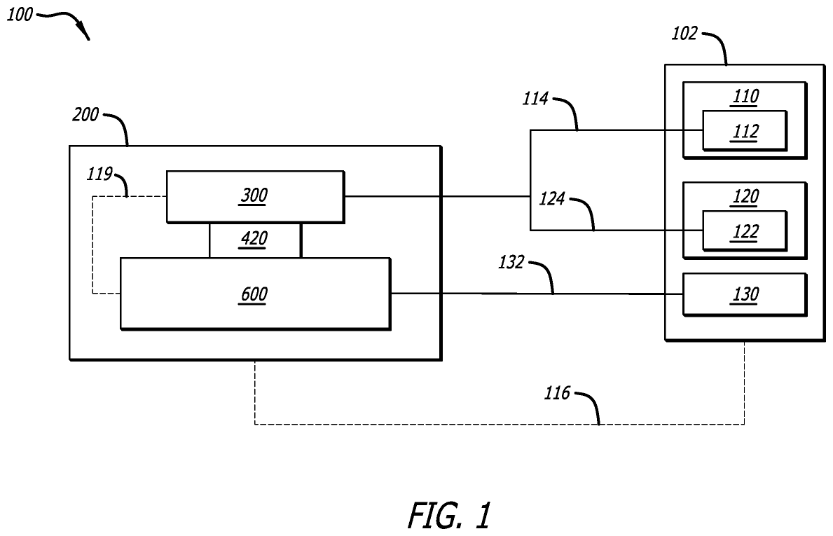

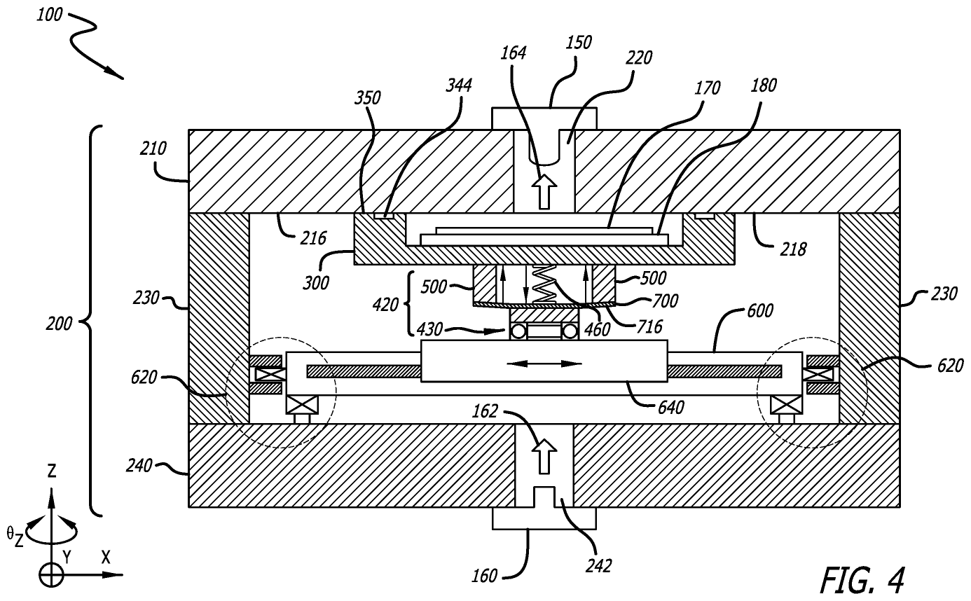

FIG. 1 shows a schematic of an exemplary multi-axis motion system 100. In one embodiment, the system 100 comprises at least one structure assembly 200 configured to support at least one carriage assembly 600 thereon. At least one pivoting decoupling system 420 is rotatably mounted to the carriage assembly 600, the pivoting decoupling system 420 configured to support at least one chuck support assembly 300, the chuck support assembly 300 configured to support at least one semiconductor wafer chuck 180 with at least one semiconductor wafer 170 positioned thereon (see FIG. 4). The chuck support assembly 300 is configured to ride on an air bearing created between elements of the chuck support assembly 300 and the structure assembly 200. At least one system controller 102 is provided that may include at least one pressure control system 110, at least one vacuum control system 120, and at least one motion control system 130. The pressure control system 110 may include at least one fluid pressure source 112 in communication with the chuck support assembly 300 via at least one fluid pressure conduit 114. Exemplary fluid pressure sources include, without limitation, pumps, pressure reservoirs, accumulators, and the like. The vacuum control system 120 may include at least one vacuum source 122 in communication with the chuck support assembly 300 via at least one vacuum conduit 124. Exemplary vacuum sources include, without limitation, vacuum pumps, vacuum reservoirs, vacuum tanks, and the like. The system controller 102 is configured to command the pressure control system 110 and the vacuum control system 120 to provide fluid pressure from the fluid pressure source 112, and/or so supply vacuum from the vacuum source 122 as required to operate the air bearing functions and/or the vacuum clamping functions of the chuck support assembly 300. For example, the system controller 102 may command the pressure control system 110, the vacuum control system 120, and the motion control system 130 to function separately or synchronously in response to commands from the system controller in a variety of modes (as will be described in detail below). The system controller 102 may further include at least one motion control system 130 in communication with the carriage assembly 600 via at least one motion control conduit 132.

As will be described below, to achieve high stability of the position of the semiconductor wafer during inspection or processing steps, the chuck support assembly 300 can be decoupled from the carriage assembly 600 through the use of the pivoting decoupling system 420, allowing the chuck support assembly 300 to be clamped to the structure assembly 200 using the vacuum functions of the chuck support assembly 300 and the vacuum control system 120.

In an alternative embodiment, any one of the pressure control system 110, the vacuum control system 120 and the motion control system 130, may be located on or integrated into the structure assembly 200, the chuck support assembly 300, the carriage assembly 600 or any combination thereof. As such, an alternative control conduit 116 may extend from the system controller 102 to the structure assembly 200, the chuck support assembly 300, or the carriage assembly 600, or a combination thereof, in order to provide control commands to the pressure control system 110, the vacuum control system 120, or the motion control system 130. For example, use of the alternative control conduit 116 may enable the location of various elements of motion control system 130 (e.g., electrical relays, solenoids, capacitors, firmware, and the like) on the carriage assembly 600 in order to provide improved dynamic control response and closed-loop feedback to the positioners mounted to the carriage assembly 600, relative to the dynamic response if those elements of the motion control system 130 were located within the system controller 102 and the motion control conduit 132 is used. In another embodiment, control commands from the system controller 102 and the motion control system 130 may be communicated the positioners wirelessly. Also, an alternative conduit 119 may extend from the carriage assembly 600 to the chuck support assembly 300, thereby enabling the location of the fluid pressure source 112 and the vacuum source 122 on the carriage assembly 600, thereby potentially providing improved performance (e.g., improved dynamic response or stability) of the air bearing and vacuum clamping functions of the chuck support assembly 300.

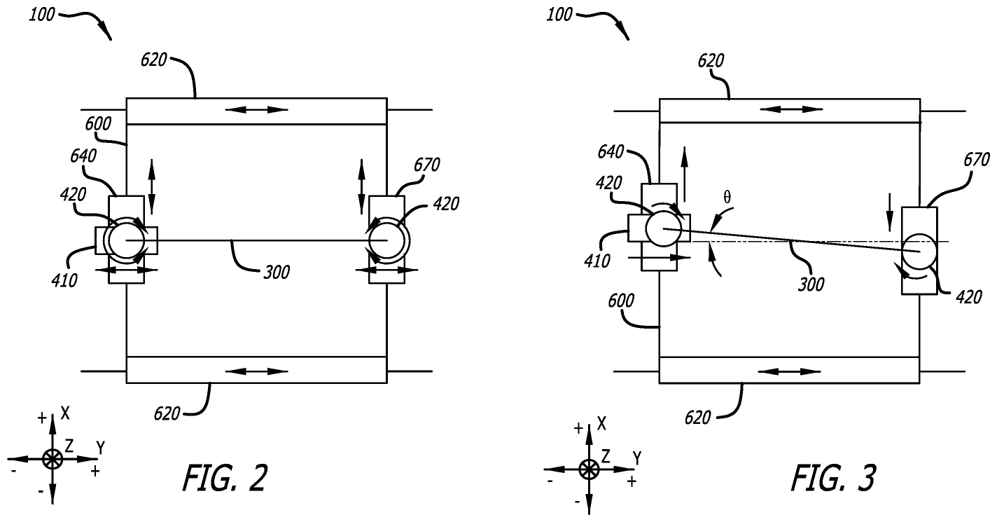

FIGS. 2 and 3 show various views of a motion system schematic showing exemplary positional states of an embodiment of the multi-axis motion system 100. As shown in FIG. 2, the carriage assembly 600 includes elements of at least one first positioner 620 configured to support the carriage assembly 600 and position it (and the chuck support assembly 300) in at least a first direction or axis (e.g., in the ±Y-direction or axis) in response to commands from the motion control system 130. At least one second positioner 640 is mounted on one end of the carriage assembly 600, the second positioner 640 being configured to position at least a portion of the chuck support assembly 300 in at least a second direction or axis (e.g., the ±X-direction). At least one third positioner 670 is mounted on the opposing end of the carriage assembly 600, the third positioner 670 configured to selectively position another portion of the chuck support assembly 300 in the second direction (e.g., the ±X-direction) independently of the second positioner 640. In the illustrated embodiment, the first and second directions are substantially orthogonal to each other, though it will be appreciated that the first direction and the second direction may not be substantially orthogonal to each other. In response to control commands from the motion control system 130, the second positioner 640 and the third positioner 670 may move in the same direction (e.g., either the +X-direction or the −X-direction). Also, the motion control system 130 may selectively command the second positioner 640 and the third positioner 670 to move in opposing directions (e.g., the second positioner 640 in the +X-direction and the third positioner 670 in the −X-direction, or vice versa), thereby causing the chuck support assembly 300 to undergo a change in angular orientation with respect to the carriage assembly 600. Also, the motion control system 130 may command the positioners 620, 640 and 670 separately, sequentially, or synchronously relative to each other.

Referring to FIGS. 2 and 3, in the illustrated embodiment, the chuck support assembly 300 may be mounted on a pair of pivoting decoupling systems 420 rotatably secured to at least one of the second positioner 640, the third positioner 670, or on at least one decoupling linkage assembly 410 that is mounted to at least one of the second positioner 640 and the third positioner 670. In the illustrated embodiment, the decoupling linkage assembly 410 is configured to allow the pivoting decoupling system 420 to freely slide in the first direction (±Y) while constraining movement of the pivoting decoupling system 420 in the second direction (±X). During use, the chuck support assembly 300 may be translated by the positioners 640 and 670 in either the +X or −X-direction. In addition, the chuck support assembly 300 may undergo a change in angular orientation about a third axis (or direction) Z (hereinafter referred to as θZ), when the positioners 640 and 670 are commanded to selectively or synchronously move in opposing X-directions, as shown in FIG. 3. In this embodiment, the pivoting decoupling systems 420 are free to rotate relative to the positioners 620, 640, and 670, thereby allowing the chuck support assembly 300 to be positioned in θZ. In this embodiment, the chuck support assembly 300 has a fixed transverse dimension (e.g., width or length), such that the distance between the pivoting decoupling systems 420 is also fixed. During operation, when the positioners 640 and 670 selectively move in opposing X-directions (e.g., so that the chuck support assembly 300 undergoes a change in angular orientation in θZ) at least one of the pivoting decoupling systems 420 must be allowed to travel freely in the ±Y-direction as needed, on the decoupling linkage assembly 410. For example, as shown in FIG. 3, the second positioner 640 may be actuated in the +X-direction and the third positioner 670 may be actuated in the −X-direction, causing the chuck support assembly 300 to undergo a change in angular orientation in θZ of about 5 degrees, though those skilled in the art will appreciate that the change in angular orientation may be greater than or less than 5 degrees. In this example, both pivoting decoupling systems 420 rotate in +θZ, and one pivoting decoupling system 420 is mounted on the decoupling linkage assembly 410 on second positioner 640, allowing the pivoting decoupling system 420 move freely in the +Y-direction. In the illustrated embodiment, a pair of first positioners 620 are arranged to position the carriage assembly 600 in the Y-direction (as described below with respect to FIGS. 4-6). Optionally, the carriage assembly 600 may be moved in the Y-direction by a single first positioner 620. As such, during operation of the multi-axis motion system 100, the chuck support assembly 300 may be positioned in the ±X-direction, the ±Y-direction, and in θZ, in response to commands from the motion control system 130.

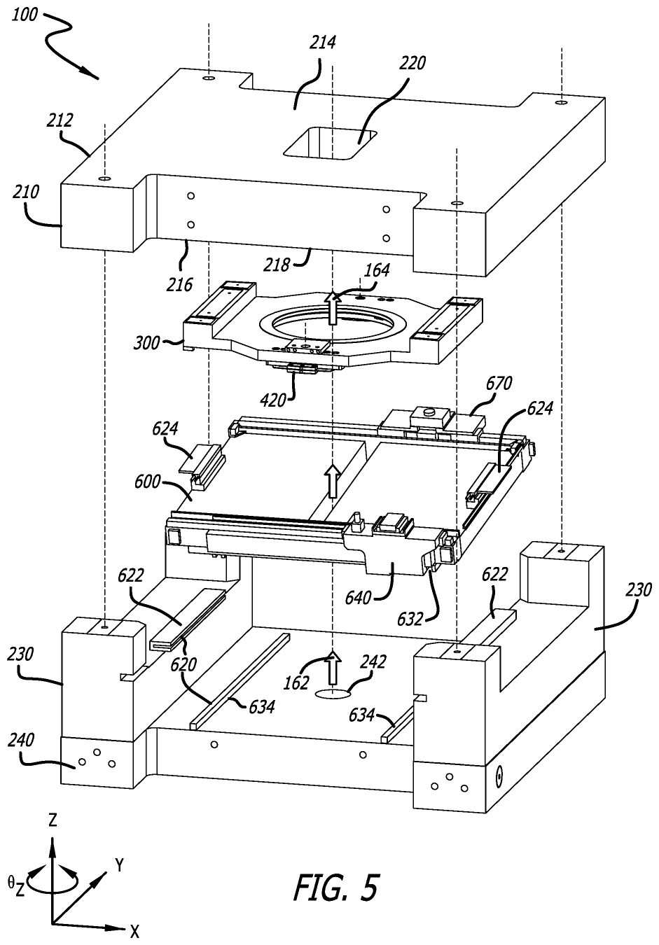

FIGS. 4 and 5 show a side view and an exploded perspective view, respectively, of an embodiment of the multi-axis motion system 100. As shown in FIG. 4, the carriage assembly 600 is supported on the structure assembly 200 that includes a lower structure 240 with at least one aperture 242 formed therein and one or more intermediate structures 230 mounted thereto. At least one upper structure 210 is secured to the intermediate structures 230, the upper structure 210 including an upper structure body 212 with at least one upper surface 214 (see FIG. 5) and at least one lower surface 216. At least one aperture 220 is formed in the upper structure 210, extending from the upper surface 214 to the lower surface 216. The upper structure 210 further includes at least one passive reference surface 218 formed on the lower surface 216. In this embodiment, the passive reference surface 218 is configured to allow the chuck support assembly 300 to move in the X- and Y-directions on an air bearing.

Referring to FIG. 4, the structure assembly 200 is configured to allow a variety of inspection and/or process instruments or tools to be installed thereon. For example, in one embodiment, an inspection device 150 (e.g., a camera or detector) may be installed above or within the aperture 220 formed in the upper structure 210. An illumination source 160 may be installed below or within the aperture 242 formed in the lower structure 240, the illumination source 160 configured to project illumination 162 incident on the underside of the wafer 170. In the illustrated embodiment, the inspection device 150 is configured to detect the illumination 164 that is transmitted through the wafer 170. As described below, in one embodiment, the carriage assembly 600 and chuck support assembly 300 may have openings or apertures formed in them that allow the illumination 162 to reach the underside of the wafer 170. Those skilled in the art will appreciate that the multi-axis motion system 100 may be configured to enable any variety of inspection or process steps to be performed on the wafer 170. For example, an illumination source may also be positioned in the aperture 220 and the inspection device 150 may sense illumination that is reflected from the semiconductor wafer 170. The illumination 162 can be provided as light in the ultraviolet, visible or infrared spectral ranges, or as X-rays. Those skilled in the art will appreciate that any variety of inspection or process tools may be positioned within the apertures 220 and 242.

In the illustrated embodiment, the volumetric space between the chuck support assembly 300, the wafer chuck 180, the wafer 170, the upper structure 210 and the inspection device 150 is open to atmospheric pressure. Alternatively, this volumetric space may be sealed so that a vacuum can be drawn in this volume, enabling certain vacuum-related processes or inspection steps to be performed on the wafer 170.

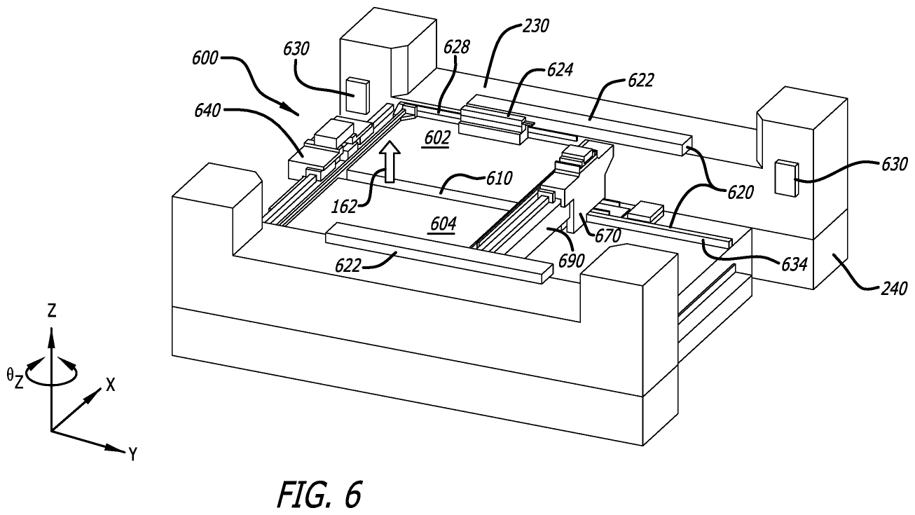

FIGS. 4-6 show various view of the carriage assembly 600 and the first positioner 620. In the illustrated embodiment, a portion of the first positioner 620 is mounted to the lower structure 240, and a portion of the first positioner 620 is mounted to the intermediate structures 230. Specifically, the first positioner 620 includes one or more sliding blocks 632 configured to travel along one or more guide rails 634 that are mounted to the base structure 640. The first positioner 620 includes a linear motor actuator with one or more linear motor magnet assemblies 622 mounted on the intermediate structure 230, and corresponding linear motor coil assemblies 624 secured to the carriage assembly 600 by at least one motor coil mount 626, the linear motor coil assemblies 624 configured to travel within the linear motor magnet assemblies 622. The carriage assembly 600 is supported on the sliding blocks 632 to allow the carriage assembly 600 to move in the ±Y-direction. In the illustrated embodiment, a linear motor actuator may be used to provide an electromotive actuation force between the intermediate structure 230 and the carriage assembly 600 without a mechanical connection, thereby allowing the first positioner 620 to be turned off (e.g., in response to one or more commands from the motion control system 130) thereby releasing the carriage assembly 600 and the chuck support assembly 300 from any actuation force in the Y-direction when the chuck support assembly 300 is vacuum-clamped to the upper structure 210. In another embodiment, both the linear motor magnet assemblies 622 and the corresponding linear motor coil assemblies 624 may be mounted on the intermediate structure 230, or they may both be mounted to the lower structure 240. As shown in FIG. 6, one or more limit switch assemblies 630 may be located on opposing ends of the intermediate structure 230, the limit switch assemblies 630 configured to detect the presence of the carriage assembly 600, sending a signal to the motion control system 130 indicating that the carriage assembly 600 has reached either end of the guide rails 634. Optionally, the limit switch assemblies 630 may not be used. At least one encoder 628 configured to provide feedback to the motion control system 130 about the location of the carriage assembly 600 is mounted on the intermediate structure 230.

While in the illustrated embodiment the actuators used in the positioners 620, 640 and 670 are linear motors, those skilled in the art will appreciate that any variety of actuators may be used. For example, in one embodiment, the actuators may be provided as lead screws (or ball screws) driven by servo motors, stepper motors, or piezo motors, wherein the electrical power to such motors can be turned off when the chuck support assembly 300 is clamped to the passive reference surface 218. Optionally, a mechanical linkage such as a clutch or gear located between such motors and their lead screws may be configured to disengage the motor from the lead screw when the chuck support assembly 300 is clamped to the passive reference surface 218.

As shown in FIG. 4, the chuck support assembly 300 may be supported on the carriage assembly 600 by at least one pivoting decoupling system 420. In the illustrated embodiment, the pivoting decoupling system 420 includes at least one pivot assembly 430 (including at least one biasing device 460), at least one decoupling interface device 700, and at least one interface assembly 500. In the illustrated embodiment, the pivoting decoupling system 420 is configured to transmit actuating forces from any one of the positioners 620, 640, 670 in the X- and Y-directions, but to allow the chuck support assembly 300 to move freely in the ±Z direction, and to freely undergo a change in angular orientation in θZ relative to the positioners 620, 640, 670. In the illustrated embodiment, the biasing device 460 is configured to exert a biasing force between the chuck support assembly 300 and the pivot assembly 430. An opposing biasing force may be created by the flexure regions 716 of the decoupling interface device 700 (as described below), resulting in a net preload force to the chuck support assembly 300 against the passive reference surface 218.

As shown in FIG. 4, the chuck support assembly 300 includes one or more active reference surfaces 350 and one or more vacuum regions 344 formed on the chuck support assembly 300. When the chuck support assembly 300 is in motion between a first position and a second position relative to the aperture 220, positive fluid pressure between the active reference surface 350 and the passive reference surface 218 may be partially balanced by a negative pressure (e.g., a vacuum preload) in the vacuum region 344, thereby creating an air bearing, and allowing the chuck support assembly 300 to be positioned relative to the aperture 220.

As described above, the system controller 102 may command the pressure control system 110, the vacuum control system 120, and the motion control system 130 to operate in a variety of modes. An exemplary mode of operation is an “unclamping mode” mode wherein the system controller 102 commands the vacuum control system 120 to reduce or eliminate the vacuum supplied to the vacuum region 344. The unclamping mode may also include a step where the system controller 102 commands the pressure control system 110 to increase the positive pressure supplied to the active reference surface 350.

Another exemplary mode of operation is an “air bearing” mode, wherein the pressure control system 110 supplies increased fluid pressure to the active reference surface 350, while the vacuum control system 120 synchronously reduces the amount of vacuum supplied to the vacuum region 344 (relative to that used in the clamping mode) to provide sufficient preload for proper air bearing operation. In an alternative air bearing mode, the vacuum supplied to the vacuum regions 344 may be turned off, and a preload is supplied by the biasing device 460. Continuing execution of the air bearing mode, the system controller 102 may command the motion control system 130 to engage one or more of the positioners 620, 640, 670 to move the chuck support assembly 300 from a first position to a second position on the air bearing (e.g., as created between the active reference surface 350 and the passive reference surface 218 along the passive reference surface 218) relative to the aperture 220 of the upper assembly 210. Those skilled in the art will appreciate that the air bearing mode may be executed by any variety or arrangement of control commands communicated from the system controller 102 to the control systems 110, 120 and 130. Also, the various steps executed by the control systems 110, 120 and 130 may occur synchronously, or in any order or sequence desired or beneficial.

Another exemplary mode of operation is a “clamping” mode, wherein the system controller 102 commands the pressure control system 110 to reduce the positive fluid pressure supplied to the active reference surfaces 350, while the vacuum control system 120 synchronously increases the amount of vacuum supplied to the vacuum regions 344. Also, system controller 102 may command the motion control system 130 to turn off the positioners 620, 640, and 670, thereby vacuum-clamping the chuck support assembly 300 to the passive reference surface 218 relative to the aperture 220. The various steps executed by the control systems 110, 120 and 130 may occur synchronously, or in any order or sequence desired or beneficial.

FIGS. 5-7 show various views of the carriage assembly 600. In the illustrated embodiment, the carriage assembly 600 includes a first carriage body 602 and a second carriage body 604. An opening or aperture 610 may be formed or arranged between the first carriage body 602 and the second carriage body 604 to allow the illumination 162 from the illumination source 160 to pass therebetween or therethrough. A first guide rail base 606 configured to support the second positioner 640 may be mounted to one end of the first carriage body 602 and the second carriage body 604. A second guide rail base 608 configured to support the third positioner 670 may be mounted to the opposite ends of the first carriage body 602 and the second carriage body 604. Those skilled in the art will appreciate that the carriage assembly 600 may have a single carriage body with an aperture 610 formed therein to allow the illumination 162 to pass therethrough.

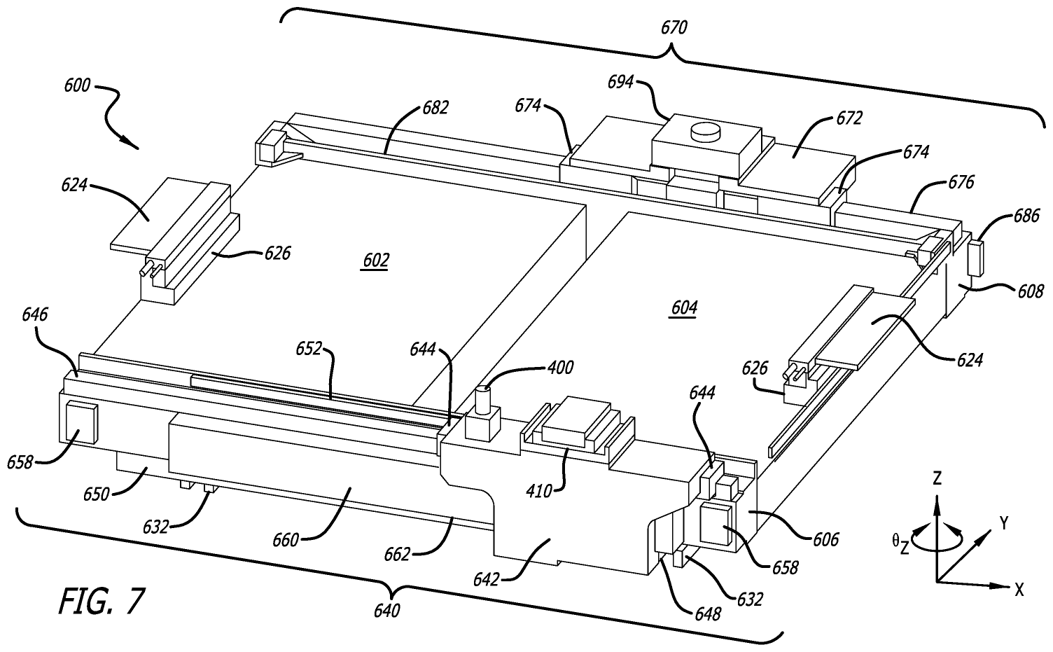

In the illustrated embodiment, as shown in FIG. 7, the second positioner 640 is provided as a frame 642 mounted on one or more sliding blocks 644 configured to travel in the X-direction along an upper guide rail 646 mounted to the first guide rail base 606. The actuation force is provided by a linear motor actuator comprising one or more linear motor magnet assemblies 660 mounted to the first guide rail base 606, the motor linear magnet assemblies 660 being configured to accept corresponding linear motor coil assemblies 662 (mounted to the frame 642) to travel therein. As is the case with the first positioner 620, in this embodiment, a linear motor actuator is used with the second positioner 640 to provide an actuation force between the first guide rail base 606 and the frame 642 without using a mechanical connection, thereby allowing the second positioner 640 to be turned off when the chuck support assembly 300 is clamped to the upper structure 210. Optionally, as described above with respect to the first positioner 620, any variety of actuators may be used with the second positioner 640. In the illustrated embodiment, the frame 642 is also mounted to at least one lower sliding block 648 configured to slide along a lower guide rail 650 that is mounted to the first guide rail base 606, thereby providing additional stiffness to the second positioner 640. Optionally, the lower sliding block 648 and the lower guide rail 650 need not be used. An encoder 652 configured to provide feedback on the location of the second positioner 640 to the motion control system 130 may be mounted to the first guide rail base 606. One or more limit switch assemblies 658 may be secured to the first guide rail base 606, the limit switch assemblies 658 configured to detect the presence of the frame 642, sending a signal to the motion control system 130 indicating that the frame 642 has nearly reached either end of the guide rails 646, 650. Optionally, the limit switch assemblies 658 need not be used, and the motion control system 130 may use signals from the encoder 652 to detect when the frame nears the end of the guide rails 646, 650.

FIG. 7 also shows a view of the third positioner 670, provided as a frame 672 mounted to one or more sliding blocks 674 configured to selectively travel in the X-direction along an upper guide rail 676 mounted to the second guide rail base 608. The actuation force on the frame 672 is provided by a linear motor comprising one or more linear motor magnet assemblies 690 (shown in FIG. 6) mounted to the second guide rail base 608, the linear motor magnet assemblies 690 configured to accept corresponding linear motor coil assemblies (not shown) therein. As is the case with the second positioner 640, the linear motor configuration used with the third positioner 670 provides an actuation force between the second guide rail base 608 and the frame 672 without using a mechanical connection, thereby allowing the third positioner 670 to be turned off when the chuck support assembly 300 is clamped to the passive reference surface 218. Alternative actuators have been described above. In the illustrated embodiment, the frame 672 is also mounted to at least one lower sliding block (not shown) configured to slide along a lower guide rail (not shown) that is mounted to the second guide rail base 608. Optionally, a lower sliding block and a lower guide rail need not be used. An encoder 682 configured to provide feedback on the location of the third positioner 670 to the motion control system 130 may be mounted to the second guide rail base 608. One or more limit switch assemblies 686 may be secured to the second guide rail base 608, the limit switch assemblies 686 configured to detect the presence of the frame 672, sending a signal to the motion control system 130 indicating that the frame 672 has nearly reached either end of the guide rails. Optionally, the limit switch assemblies 686 need not be used, and the motion control system 130 may use signals from the encoder 682 to detect when the frame 672 nears the end of the guide rails.

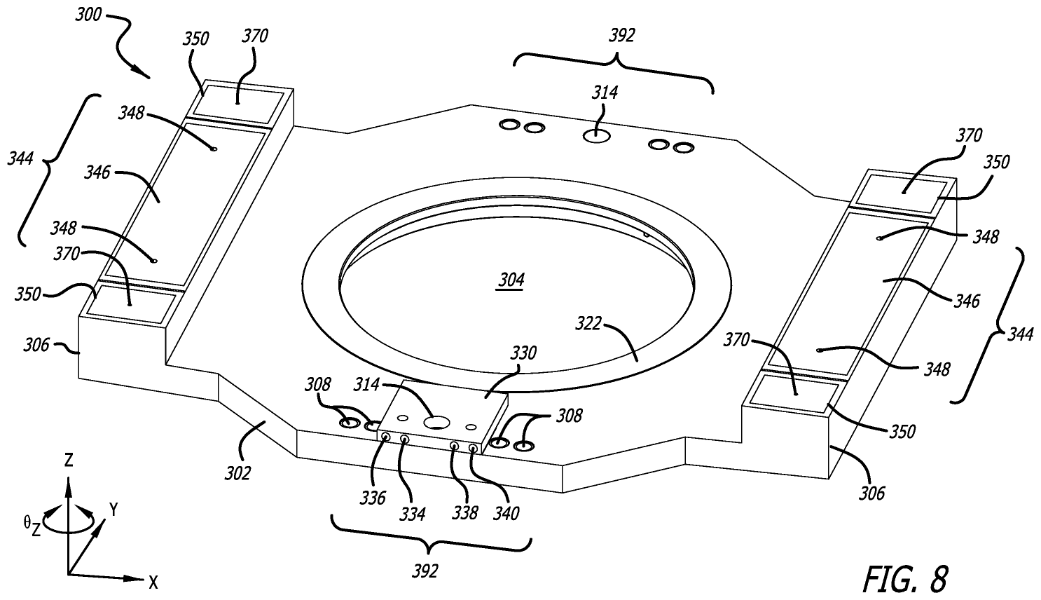

FIG. 8 shows a view of an embodiment of the chuck support assembly 300. In this embodiment, the chuck support assembly 300 includes a chuck support body 302 with at least one aperture 304 formed therein. In the illustrated embodiment, the chuck support body 302 is made from a ceramic material, although those skilled in the art will appreciate that the chuck support body may be made from an variety of materials. As described above, the aperture 304 is configured to allow illumination 162 to reach the underside of the semiconductor wafer 170 (see FIG. 5). In addition, the aperture 304 is configured to allow lift pins (not shown) to access the underside of the semiconductor wafer 170 when it is placed in, or removed from, the wafer chuck 180 (see FIG. 4). At least one chuck receiving recess 322 configured to support the wafer chuck 180 therein is formed in the chuck support body 302. The wafer chuck 180 may be secured within the chuck receiving recess 322 by negative pressure (vacuum) from one or more vacuum ports (not shown) formed the chuck receiving recess 322, the vacuum ports in communication with at least one vacuum inlet 338 formed in at least one manifold 330 via one or more vacuum passages (not shown). The wafer chuck 180 may be detached from the chuck receiving recess 322 by fluid pressure routed from a fluid pressure port formed in the manifold 330 to the chuck receiving recess 322.

As shown in FIG. 8, in the illustrated embodiment, one or more raised regions 306 are formed on opposing sides of the aperture 304. A plurality of active reference surfaces 350 are formed on the raised regions 306, the active reference surfaces 350 configured to form a portion of an air bearing when positioned proximal to the passive reference surface 218 formed on the upper structure 210, as described above. At least one fluid pressure port 370 is formed in each active reference surface 350, the fluid pressure ports 370 in fluid communication with at least one fluid pressure inlet 336 formed in the manifold 330 via one or more fluid pressure passages (not shown). In the illustrated embodiment, the fluid pressure passages are flexible tubes routed from the fluid pressure ports 370 to the manifold 330. Optionally, the fluid pressure passages may be formed integral to the chuck support body 302. Those skilled in the art will appreciate that any variety of air bearing configurations may be used. For example, the fluid pressure may be supplied to the active reference surfaces 350 through a plurality of pores formed in the material of the chuck support body 302.

In the illustrated embodiment, the air bearing functions of the multi-axis motion system 100 include a vacuum preload or biasing force between the chuck support assembly 300 and the passive reference surface 218 (e.g., in response to commands from the vacuum control system 120). Accordingly, at least one vacuum region 344 is formed on the raised areas 306 of the chuck support body 302. The vacuum region 344 includes at least one vacuum recess 346 formed in the raised region 306. One or more vacuum ports 348 are formed in each vacuum recess 346, the vacuum ports 348 arranged in communication with at least one vacuum inlet 334 formed in the manifold 330 via one or more vacuum passages (not shown). The vacuum region 344 is also operative to clamp the chuck support assembly 300 to the passive reference surface 218, for example, if the pressure control system 110 reduces the fluid pressure supplied to the active reference surface 350. In the illustrated embodiment, the vacuum passages are flexible tubes or hoses routed from the vacuum ports 348 to the manifold 330. Optionally, the vacuum passages may be formed integral to the chuck support body 302.

In the illustrated embodiment, fluid pressure is supplied to the fluid pressure inlets 336, 340 on the manifold 330 from the fluid pressure source 112 via the fluid pressure conduit 114. Optionally, the fluid pressure source 112 may be located on the carriage assembly 600, and fluid pressure may be communicated to the fluid pressure inlets 336, 340 via the alternative conduit 119 (described in detail above). Vacuum is supplied to the vacuum inlets 334, 338 from the vacuum source 122 via the vacuum conduit 124. Optionally, the vacuum source 122 may be located on the carriage assembly 600, and vacuum may be communicated to the vacuum inlets 334, 338 via the alternative conduit 119 (described in detail above).

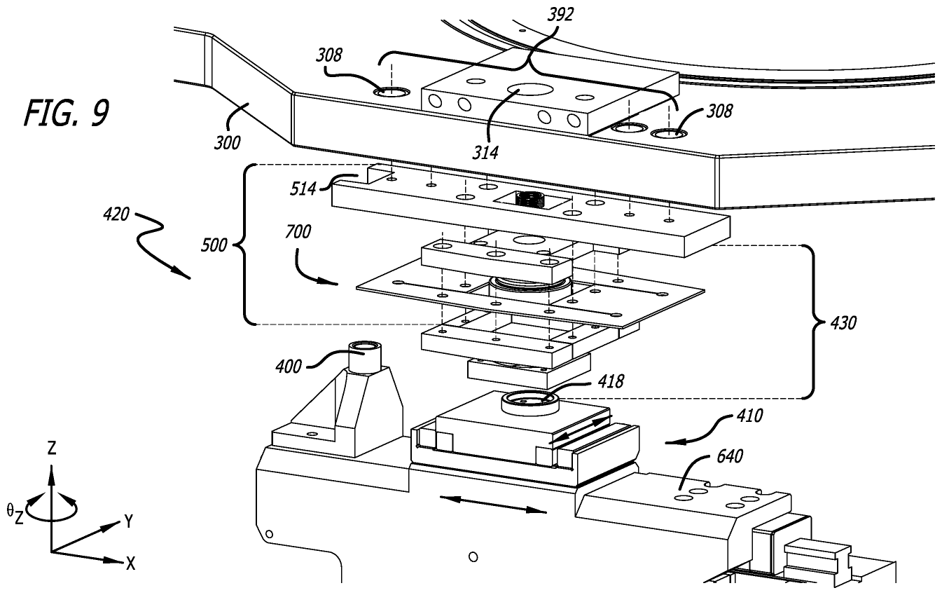

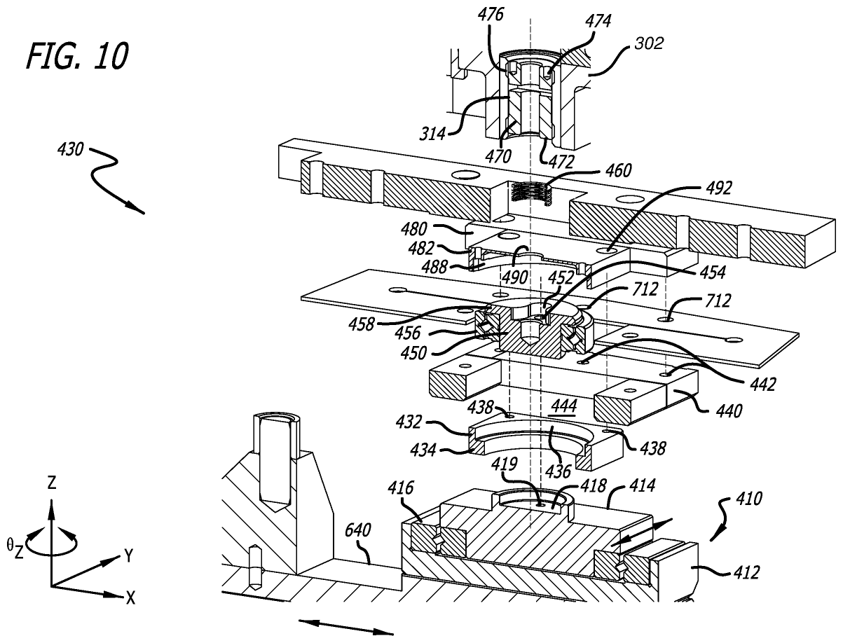

As shown in FIGS. 8-10, in the illustrated embodiment, the chuck support assembly 300 is coupled to the pivoting decoupling system 420 at one or more connection regions 392 formed on the chuck support body 302. In the illustrated embodiment, there are two connection regions 392, located on opposing sides of the aperture 304. Optionally, there need be only one connection region 392. The connection regions 392 include a plurality of coupling passages 308 formed in the chuck support body 302, the coupling passages 308 being configured to accept one or more fasteners or couplers (not shown) used to couple the chuck support assembly 300 to at least one interface assembly 500 (shown in FIGS. 9, 12 and 13). Exemplary types of couplers include, without limitation, machine screws, cap screws, bolts, rivets, pins, welds, and the like. Those skilled in the art will appreciate that any variety of couplers may be used. Each connection region 392 also includes at least one pivot passage 314 formed in the chuck support body 302, the pivot passages 314 configured to accept at least one pivot seat 470 therein (see FIG. 10). In the illustrated embodiment, the pivot seat 470 engages the pivot passage 314 with threads 476, allowing the position of the pivot seat 470 in the Z-direction relative to the chuck support body 302 to be adjusted by inserting a tool (not shown) into one or more adjusting recesses 474 formed in the pivot seat 470 and turning the pivot seat 470 clockwise or counter-clockwise. The pivot seat 470 includes at least one surface 472 configured to engage at least one biasing device 460 (described below) to provide a biasing force in the Z-direction between the pivot assembly 430 and the chuck support assembly 300. Adjustment of the Z-position of the pivot seat 470 allows the user to adjust this biasing force as required for optimized performance of the multi-axis motion system 100.

FIGS. 9-13 show various views of the pivoting decoupling system 420 and its constituent sub-assemblies. Those skilled in the art will appreciate that the inclusion of sub-assemblies in this written description are intended only to more clearly recite the various features of the system and are not intended to limit the scope of the invention. As described above, during operation of the multi-axis motion system 100, when a change in the θZ orientation of the chuck support assembly 300 occurs, the connection region 392 must be allowed to rotate in θZ relative to at least one of the positioners 620, 640, 670. Also, when the wafer 170 has been located in a desired position in the X- and Y-directions (e.g., by the positioners 620, 640, 670 in response to commands from the motion control system 130), the chuck support assembly 300 must be allowed to move in the ±Z-direction (e.g., toward the passive reference surface 218) in order to vacuum-clamp the chuck support assembly 300 to the passive reference surface 218. These two requirements are enabled by the pivoting decoupling system 420.

As described above, at least one of the pivoting decoupling systems 420 or pivot assemblies 430 are mounted to a decoupling linkage assembly 410 configured to allow the pivoting decoupling system 420 to freely slide in the first direction (±Y) while constraining the movement of the pivoting decoupling system 420 in the second direction (±X). As shown in FIG. 10, the decoupling linkage assembly 410 includes at least one base 412 mounted to the second positioner 640 and configured to accept at least one linear bearing 416. At least one linkage block 414 is disposed in the inner race of the linear bearing 416, enabling the linkage block 414 to slide in the Y-direction, orthogonal to the X-direction of motion of the second positioner 640. At least one pivot recess 418 with at least one coupling passage 419 is formed in the linkage block 414, the pivot recess 418 configured to receive at least a portion of the pivot assembly 430.

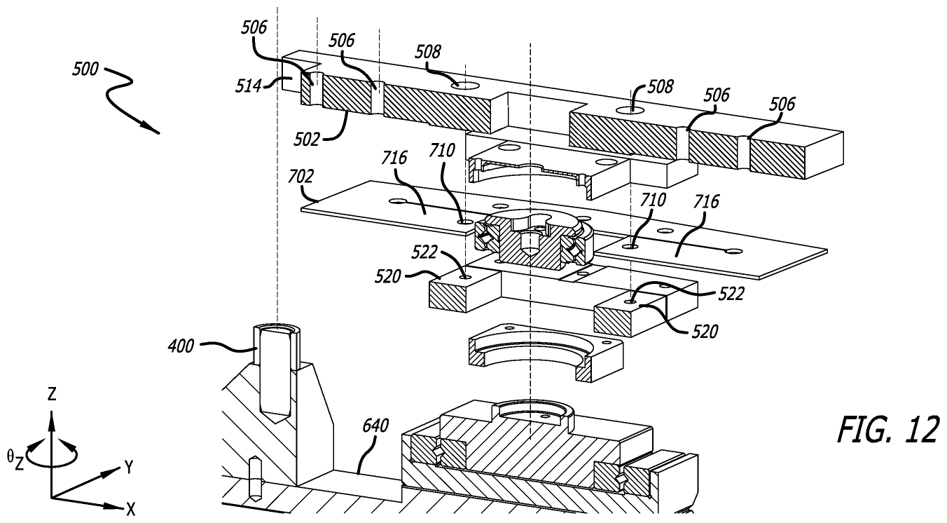

FIG. 9 shows an exploded perspective view of the pivoting decoupling system 420. In the illustrated embodiment, the pivoting decoupling system 420 comprises three intertwined devices including at least one pivot assembly 430, at least one interface assembly 500, and at least one decoupling interface device 700. The interface assembly 500 is secured to at least one of the connection regions 392 of the chuck support assembly 300 by one or more couplers (not shown) that traverse through the coupling passages 308 of the chuck support assembly 300 and engage corresponding outer coupling passages 506 in at least one interface plate 502 (see FIG. 12), thereby securing the connection region 392 to the interface assembly 500.

As shown in FIG. 10, the pivot assembly 430 is secured to the pivot recess 418 of the decoupling linkage assembly 410 that is mounted on the second positioner 640, or to the pivot mounting block 694 of the third positioner 670, by one or more couplers (not shown) that traverse though at least one coupling passage 454 formed in at least one pivot body 450. The decoupling interface device 700 is configured as a mechanical interface between the pivot assembly 430 and the interface assembly 500, operative to stiffly couple the pivot assembly 430 to the interface assembly 500 in the translational (X-Y) directions or degrees of freedom and in the rotational (8Z) degree of freedom, but to allow relative movement between the pivot assembly 430 and the interface assembly 500 in the Z-direction or degree of freedom, subject to a biasing force exerted by the flexure regions 716 of the decoupling interface device 700 (as described below). The pivot assembly 430 is operative to allow the pivoting decoupling system 420 (and the chuck support assembly 300) to rotate freely in the rotational (8Z) degree of freedom relative to the positioners 620, 640 and 670.

FIG. 10 shows an exploded perspective sectional view of an embodiment of the pivot assembly 430. As shown, the pivot assembly 430 includes at least one first bearing plate 432 having a plate body 434 with at least one recess 436 formed therein, the recess 436 configured to receive at least a portion of at least one pivot bearing 456. The pivot assembly 430 further includes at least one second bearing plate 480 having a bearing plate body 482 with at least one recess 488 formed therein, the recess 488 configured to receive at least a portion of the pivot bearing 456. The pivot bearing 456 is configured to accept at least one pivot body 450 therein. The pivot body 450 has at least one plate member or flange 458 formed thereon, and at least one recess 452 formed therein, with at least one coupling passage 454 extending through the pivot body 450. When assembled, at least one coupler (not shown) traverses through the coupling passage 454 to engage the coupling passage 419 formed in the pivot recess 418, thereby securing the pivot body 450, pivot bearing 456 and the first bearing plate 432 to the linkage block 414 of the decoupling linkage assembly 410 mounted on the second positioner 640, or, in the case of the third positioner 670, to the pivot mounting block 694.

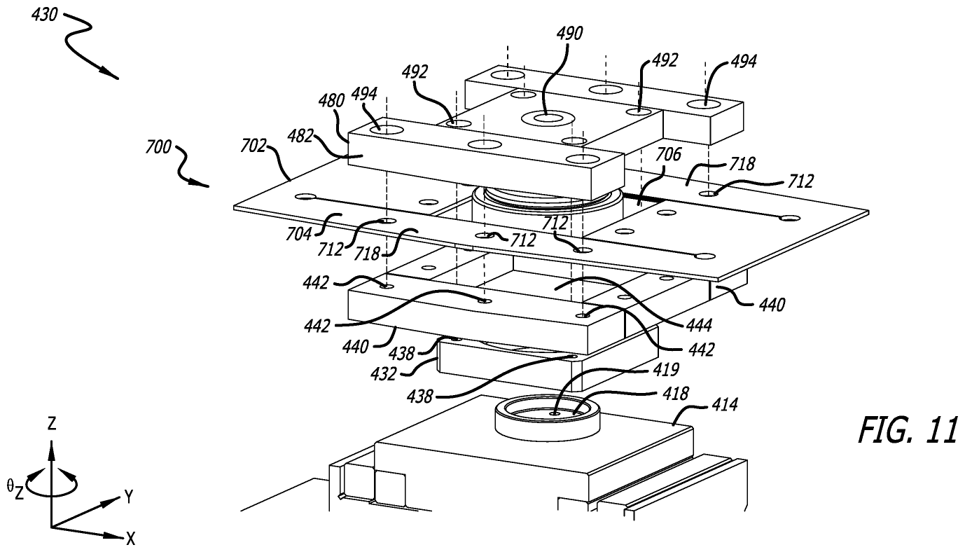

As shown in FIGS. 10 and 11, a plurality of inner coupling passages 492 are formed in the bearing plate body 482, the inner coupling passages 492 configured to accept one or more couplers (not shown) to traverse therethrough and engage the coupling passages 438 formed in the first bearing plate 432, thereby securing the second bearing plate 480 to the first bearing plate 432, and securing the pivot bearing 456 between the first bearing plate 432 and the second bearing plate 480.

The pivot assembly 430 interfaces with the chuck support assembly 300 via at least one biasing device 460 configured to engage at least one recess 490 formed in the second bearing plate 480 and with the surface 472 of at least one pivot seat 470 positioned within the pivot passage 314 of the chuck support assembly 300. In the illustrated embodiment, the biasing device 460 is provided as a multi-layer wavespring, although those skilled in the art will appreciate that the biasing device 460 may be provided as a coil spring, spring washer, or any variety of spring or biasing devices.

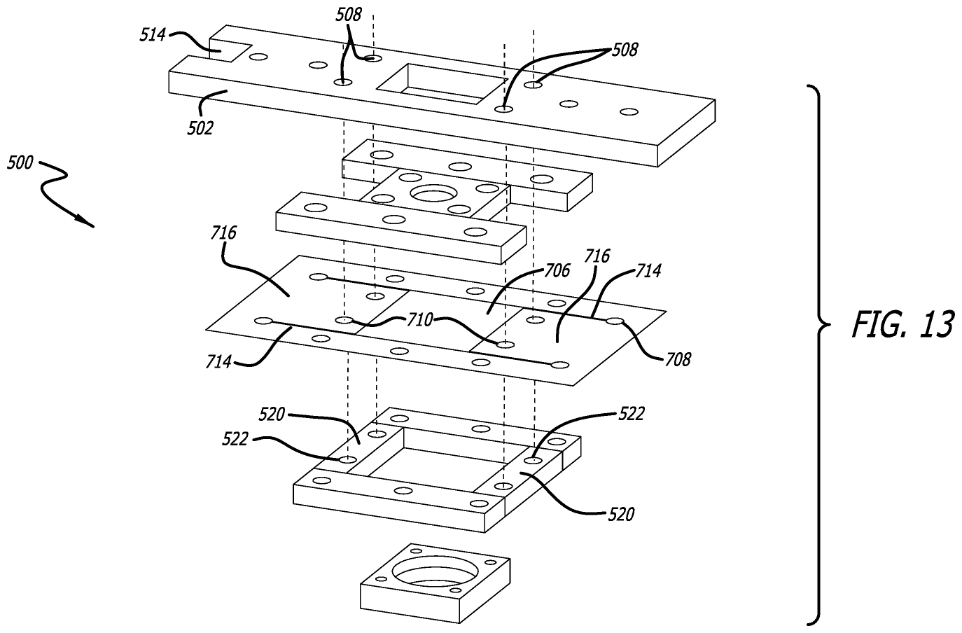

FIGS. 9-13 show various views of the decoupling interface device 700. The decoupling interface device 700 is configured to couple the interface assembly 500 to the pivot assembly 430. In the illustrated embodiment, the decoupling interface device 700 includes at least one blade member 702 having a blade member body 704 with one or more outer regions 718, at least one aperture 706, and one or more flexure regions 716 formed therein. The flexure regions 716 are defined by transversely opposed slots 714 (as shown in FIG. 13), with each slot 714 extending from the aperture 706 to a relief passage 708 configured reduce or eliminate any concentration of stress where the slots 714 end and the flexure regions 716 transitions into the rest of the blade member body 704. In the illustrated embodiment, the flexure regions 716 are operative to deflect in the Z-direction, with the deflection being greatest in the portion of the flexure region 716 closest to the aperture 706, thereby applying a biasing force in the Z-direction between the pivot assembly 430 and the interface assembly 500. A plurality of outer coupling passages 712 are formed in the outer regions 718, and a plurality of inner coupling passages 710 are formed in the flexure region 716.

In the illustrated embodiment, the flexure regions 716 are operative to act as biasing devices, so the blade member body 704 is formed from material with spring properties, such as spring steel, though those skilled in the art will appreciate that any variety of materials may be used. In the illustrated embodiment, the decoupling interface device 700 includes multiple blade member bodies 704 stacked on each other, such that the flexure regions 716 have spring/flexure properties similar to that of leaf springs. Those skilled in the art will appreciate that the decoupling interface device 700 may be formed of a single blade member body 704. In one embodiment, at least one damping material (not shown) may be placed between the blade member bodies 704, the damping material configured to prevent the generation of resonant vibrations and/or mechanical noise during operation of the pivoting decoupling system 420. Optionally, a damping material need not be used.

As shown in FIG. 11, the second bearing plate 480 of the pivot assembly 430 further comprises a plurality of outer coupling passages 494 extending therethrough, and configured to accept one or more couplers (not shown) to traverse therethrough, the couplers also traversing through the outer coupling passages 712 formed in the outer regions 718 of the blade member 702, and engaging corresponding coupling passages 442 formed in at least one outer intermediate plate member 440, thereby securely retaining the outer regions 718 of the decoupling interface device 700 to the second bearing plate 480. In the illustrated embodiment, the pivot assembly 430 includes two outer intermediate plate members 440, defining at least one aperture 444 therebetween, the aperture 444 configured to accept the bearing plate 432 and the pivot body 450 therein.

FIGS. 9, 12 and 13 show various views of an embodiment of the interface assembly 500. In one embodiment, the interface assembly 500 includes at least one interface plate 502 and one or more inner intermediate plate members 520. The interface plate 502 includes a plurality of inner coupling passages 508, a plurality of outer coupling passages 506, and at least one stop recess 514 formed therein. The inner intermediate plate member 520 includes a plurality of coupling passages 522 formed therein. When assembled, a plurality of couplers (not shown) traverse through the inner coupling passages 508, the inner coupling passages 710 in the flexure region 716 of the decoupling interface device 700, and engage the coupling passages 522, thereby securely retaining the flexure regions 716 to the interface plate 502.

FIGS. 9, 10 and 12 show various views of a stop assembly 400 configured to limit the extent of the change in angular orientation that the chuck support assembly 300 undergoes during operation of the multi-axis motion system 100. In the illustrated embodiment, the stop assembly 400 is mounted on the second positioner 640 and is operative to engage the stop recess 514 formed in the interface plate 502 of the interface assembly 500, to limit the change in angular orientation of the chuck support assembly 300. In the illustrated embodiment, there is a single stop assembly 400, mounted on the second positioner 640. Optionally, the stop assembly 400 may be mounted on the third positioner 670, or to both the second positioner 640 and the third positioner 670.

As described above, in the illustrated embodiment, the decoupling interface device 700 is operative to couple the pivot assembly 430 to the interface assembly 500 in the X- and Y-directions and in θZ. Due to space constraints and the high speed (up to 300 mm/s) and acceleration (up to 5 m/s²) of the chuck support assembly 300 during operation, one design goal of the pivoting decoupling system 420 is to limit its vertical dimension (height) and its mass. FIG. 5 shows the pivoting decoupling system 420 positioned underneath the chuck support assembly 300. While in the illustrated embodiment, the decoupling interface device 700 is shown as having a thin profile, alternative embodiments of the decoupling interface device 700 may include coil springs, wave springs, wave washers, and the like, as alternative biasing devices used instead of the flexure regions 716. The X-Y mechanical connection between the pivot assembly 430 and the interface assembly 500 may also be provided as interlocking pins, splines, and the like. Those skilled in the art will appreciate that any variety of mechanical devices may be used to couple the pivot assembly 430 to the interface assembly 500 in the X- and Y-directions and in 8Z, while providing a biasing force between the pivot assembly 430 and the interface assembly 500.

As described above, the multi-axis motion system 100 can operate in a variety of sequences or modes. For example, an exemplary sequence of operation is an unclamp-step-settle-clamp-stabilization sequence. In this sequence, the system controller 102 first executes the unclamping mode (described above) by commanding the vacuum control system 120 to reduce the vacuum supplied to the vacuum region 344 of the chuck support assembly 300. The step part of the sequence begins with the execution of the air bearing mode, wherein the air bearing is created between the active reference surface 350 and the passive reference surface 218, after which the positioners 620, 640 and 670 (or any combination thereof) accelerate (“step”) the chuck support assembly 300 on an X-Y trajectory, a 8Z trajectory (or a combination thereof) (e.g., in response to selective commands from the motion control system 130), from a first position to a second position, following by deceleration of the chuck support assembly 300 as it approaches the second position.

The “step” function is followed the “settle” function, a period that allows for any compliance, spring, or play in the moving components or subsystems (or its components) to settle out or be damped. When the “settle” function is complete, the system controller 102 executes the “clamping” mode as described above. The “clamping” mode is followed by a “stabilization” period to allow any physical transients (e.g., vibration, shock, etc.) to attenuate or be damped. The complete unclamp-step-settle-clamp-stabilization sequence may be accomplished in less than one second. Those skilled in the art will appreciate that appreciate that the multi-axis motion system 100 may operate in any variety or combination of sequences or modes in order to perform wafer inspection or other operations as determined by the system operator.

The foregoing is illustrative of embodiments and examples of the invention, and is not to be construed as limiting thereof. Although a few specific embodiments and examples have been described with reference to the drawings, those skilled in the art will readily appreciate that many modifications to the disclosed embodiments and examples, as well as other embodiments, are possible without materially departing from the novel teachings and advantages of the invention. Accordingly, all such modifications to the subject matter described herein are intended to be included within the scope of the invention as defined in the claims. For example, skilled persons will appreciate that the subject matter of any sentence, paragraph, example or embodiment can be combined with subject matter of some or all of the other sentences, paragraphs, examples or embodiments, except where such combinations are mutually exclusive. The scope of the present invention should, therefore, be determined by the following claims, with equivalents of the claims to be included therein.

What is claimed is:

1. A multi-axis motion system, comprising:
at least one structure assembly configured to support at least one first positioner operative to support and change the position of at least one carriage assembly in a first direction, the at least one carriage assembly including:
at least one second positioner secured to one end of the carriage assembly, the at least one second positioner including at least one frame configured to travel thereon in a second direction substantially orthogonal to the first direction;
at least one third positioner secured to the opposing end of the at least one carriage assembly, the at least one third positioner including at least one frame configured to selectively travel thereon in the second direction independently of the at least one frame of the at least one second positioner;
at least one decoupling linkage assembly secured to at least one of the at least one second positioner and the at least one third positioner, wherein the at least one decoupling linkage assembly is configured to allow at least one pivoting decoupling system to freely slide in the first direction;
at least one pivoting decoupling system rotatably coupled to at least one of the at least one decoupling linkage assembly, the at least one second positioner, and the at least one third positioner; and
at least one chuck support assembly including at least one connection region, the at least one connection region secured to the at least one pivoting decoupling system.

2. The multi-axis motion system of claim 1, wherein the first positioner comprises:
at least one linear motor actuator, at least one guide rail secured to the at least one structure assembly, and one or more sliding blocks configured to travel along the at least one guide rail.

3. The multi-axis motion system of claim 2, wherein the at least one linear motor actuator includes at least one linear motor magnet assembly secured to the at least one structure assembly, and at least one linear motor coil assembly secured to the at least one carriage assembly.

4. The multi-axis motion system of claim 1, wherein the first positioner is selected from the group consisting of servo-motor driven linear motion stages, stepper motor-driven linear stages and piezomotor-driven motion stages.

5. The multi-axis motion system of claim 1, wherein the at least one structure assembly comprises:
at least one lower structure;
at least one intermediate structure secured to the at least one lower structure; and
at least one upper structure secured to the at least one intermediate structure, the at least one upper structure having at least one upper structure body with at least one lower surface, with at least one passive reference surface formed thereon, the at least one upper structure further comprising at least one aperture formed in the at least one upper structure body.

6. The multi-axis motion system of claim 5, wherein the at least one lower structure includes at least one aperture formed therein.

7. The carriage assembly of claim 1, further comprising:
at least one first carriage body;
at least one first guide rail base secured to one end of the at least one first carriage body;
at least one second guide rail base secured to the opposing end of the at least one first carriage body;
at least one second positioner mounted on the at least one first guide rail base, the at least one second positioner including at least one frame configured to travel in the second direction; and
at least one third positioner mounted on the at least one second guide rail base, the at least one third positioner including at least one frame configured to selectively travel in the second direction independently of the at least one frame of the at least one second positioner.

8. The carriage assembly of claim 7, further comprising a second carriage body.

9. The multi-axis motion system of claim 1, wherein the at least one pivoting decoupling system comprises:
at least one pivot assembly configured to be rotatably secured to the decoupling linkage assembly;
at least one interface assembly, configured to be secured to the chuck support assembly;
at least one decoupling interface device including at least one blade member with at least one outer region configured to be secured to the at least one pivot assembly, and at least one flexure region configured to be secured to the at least one interface assembly; and
wherein the at least one decoupling interface device is operative to transmit actuating forces from the at least one pivot assembly to the at least one interface assembly in at least one of the first direction and the second direction, and to provide a biasing force between the at least one pivot assembly and the at least one interface assembly in a third direction.

10. The multi-axis motion system of claim 9, wherein the at least one decoupling interface device includes a plurality of blade members with at least one damping material disposed between the blade members.

11. The multi-axis motion system of claim 1, wherein the at least one pivoting decoupling system comprises:
at least one decoupling interface device including at least one blade member having at least one blade member body with at least one aperture, one or more outer regions, a plurality of outer coupling passages, a plurality of inner coupling passages, and one or more flexure regions formed therein;
at least one pivot assembly including:
at least one first bearing plate having at least one first bearing plate body with at least one bearing recess and one or more coupling passages formed therein, the at least one bearing recess configured to accept a portion of at least one pivot bearing therein, the at least one pivot bearing configured to accept at least one pivot body therein;
at least one second bearing plate including at least one second bearing plate body with a least one bearing recess formed therein, the at least one bearing recess configured to accept a portion of the at least one pivot bearing therein, the at least one second bearing plate body further including one or more inner coupling passages and one or more outer coupling passages formed therein; and
one or more couplers configured to traverse through the inner coupling passages in the at least one second bearing plate body and engage the coupling passages in the at least one first bearing plate, thereby retaining the at least one pivot bearing between the at least one first bearing plate and the at least one second bearing plate;
one or more outer intermediate plate members with a plurality of coupling passages formed therein; and
a plurality of couplers configured to traverse through the outer coupling passages of the at least one second bearing plate, through a plurality of outer coupling passages of the at least one blade member body, to engage the coupling passages in the outer intermediate plate members, thereby securely retaining the at least one outer region of the at least one blade member body between the at least one second bearing plate and the outer intermediate plate members; and
at least one interface assembly, including:
at least one interface plate with a plurality of outer coupling passages and a plurality of inner coupling passages formed therein, and one or more inner intermediate plate members with a plurality of coupling passages formed therein; and
a plurality of couplers configured to traverse through the inner coupling passages of the at least one interface plate and the inner coupling passages of the at least one blade member body, and engage the coupling passages formed in the inner intermediate plate members, thereby securing the flexure regions of the at least one blade member body between the at least one interface plate and the inner intermediate plate members.

12. The multi-axis motion system of claim 1, wherein the at least one chuck support assembly includes:
at least one chuck support body with at least one aperture formed therein;
at least one connection region configured to be secured to the pivoting decoupling systems;
a plurality of raised regions formed on the at least one chuck support body;
at least one fluid pressure inlet in communication with at least one fluid pressure source via at least one fluid pressure conduit;
at least one vacuum inlet in communication with at least one vacuum source via at least one vacuum conduit;
a plurality of fluid pressure passages formed in the at least one chuck support body;
a plurality of vacuum passages formed in the at least one chuck support body;
one or more active reference surfaces formed on the raised regions, the active reference surfaces including one or more fluid pressure ports formed therein, the fluid pressure ports in fluid communication with the at least one fluid pressure inlet via the fluid pressure passages;
one or more vacuum recesses formed in the raised regions, the vacuum recesses including one or more vacuum ports formed therein, the vacuum ports in pneumatic communication with the vacuum inlet via the vacuum passages; and
wherein the active reference surfaces and the vacuum recesses form an air bearing configured to allow the chuck support assembly to be positioned relative to the at least one aperture formed in the upper structure.

13. The chuck support assembly of claim 12, further comprising a second connection region configured to interface with at least one of the pivoting decoupling systems.

14. The chuck support assembly of claim 12, wherein the fluid pressure passages are connected to at least one fluid pressure source by at least one pressure conduit.

15. The multi axis system of claim 1, wherein at least one of the second and third positioner comprises:
at least one upper guide rail secured to at least one of the at least one first guide rail base and the at least one second guide rail base, including one or more upper sliding blocks configured to slide along the upper guide rail;
at least one frame secured to the upper sliding blocks;
at least one linear motor coil assembly secured to the at least one frame; and
at least one linear motor magnet assembly mounted to at least one of the at least one first guide rail base and the at least one second guide rail base, and configured to allow the at least one linear motor coil assembly to travel therein; and
wherein the at least one linear motor magnet assembly is operative to exert an electromotive force on the at least one linear motor coil assembly, thereby forcing the at least one frame to undergo a change in linear position along the at least one upper guide rail.

16. The multi axis system of claim 15, wherein at least one of the at least one second positioner and the at least one third positioner further comprises:
at least one lower guide rail secured to at least one of the at least one first guide rail base and the at least one second guide rail base, with one or more lower sliding blocks secured to the at least one frame and configured to slide along the lower guide rail;
one or more encoders secured to at least one of the at least one first guide rail base and the at least one second guide rail base, the encoders configured to sense the position of the at least one frame; and
one or more limit switch assemblies secured to at least one of the at least one first guide rail base and the at least one second guide rail base, the limit switch assemblies configured to sense the presence of the at least one frame.

17. A multi-axis motion system, comprising:
at least one system controller including at least one fluid pressure control system, at least one vacuum control system, and at least one motion control system, the at least one fluid pressure control system including at least one fluid pressure source, the at least one vacuum control system including at least one vacuum source;
at least one structure assembly configured to support at least one first positioner configured to travel in a first direction, the at least one first positioner configured to slidably support at least one carriage assembly, the at least one carriage assembly including:
at least one second positioner slidably mounted on one end of the carriage assembly, the at least one second positioner configured to travel in a second direction substantially orthogonal to the first direction; and
at least one third positioner slidably mounted on the opposite end of the at least one carriage assembly, the at least one third positioner configured to selectively travel in the second direction independently of the at least one second positioner;
at least one decoupling linkage assembly secured to the at least one second positioner, wherein the at least one decoupling linkage assembly is configured to allow the at least one pivoting decoupling system to freely slide in the first direction;
at least one first pivoting decoupling system rotatably coupled to at least one of the at least one decoupling linkage assembly, the at least one second positioner, and the at least one third positioner; and
at least one chuck support assembly including at least one connection region, the at least one connection region secured to the at least one first pivoting decoupling system.

18. The multi-axis motion system of claim 1, wherein the at least one decoupling linkage assembly is secured to the at least one third positioner.

19. A method of positioning a chuck support assembly, comprising:
providing at least one system controller operative to selectively command at least one pressure control system, at least one vacuum control system, and at least one motion control system to execute at least one of at least one unclamping mode, at least one air bearing mode and at least one clamping mode;
executing the at least one unclamping mode, comprising:
commanding the at least one vacuum control system to reduce the vacuum supplied to at least one vacuum region formed in at least one chuck support assembly proximal to at least one passive reference surface formed on at least one lower surface of at least one upper structure;
executing the at least one air bearing mode, the air bearing mode comprising:
commanding the least one pressure control system to supply fluid pressure to at least one active reference surface formed on the chuck support assembly; and
synchronously commanding the at least one motion control system to engage at least one of at least one first positioner, at least second positioner, and at least one third positioner to move the at least one chuck support assembly in at least one of a first direction and a second direction relative to at least one aperture from a first position to a second position; and
executing the at least one clamping mode, comprising:
commanding the least one pressure control system to decrease the fluid pressure supplied to the at least one active reference surface;
synchronously commanding the at least one vacuum control system to increase the vacuum supplied to at least one vacuum region; and
synchronously commanding the at least one motion control system to disengage at least one of the at least one first positioner, the at least second positioner and the at least one third positioner, thereby decoupling the chuck support assembly from the positioners and clamping it to the passive reference surface.

20. The method of claim 19, wherein the chuck support assembly undergoes a change in angular orientation relative to the at least one aperture.
